(19) United States
(12) Patent Application Publication
(10) Pub. No.: US 2025/0231477 A1
(43) Pub. Date: Jul. 17, 2025

(54) FILM FORMING APPARATUS, FILM FORMING METHOD, AND ARTICLE MANUFACTURING METHOD

(71) Applicant: CANON KABUSHIKI KAISHA, Tokyo (JP)

(72) Inventor: OSAMU YASUNOBE, Tochigi (JP)

(21) Appl. No.: 19/009,431

(22) Filed: Jan. 3, 2025

(30) Foreign Application Priority Data
Jan. 11, 2024 (JP) 2024-002789

(51) Int. Cl. G03F 7/00

(52) U.S. Cl. CPC G03F 7/0002

(57) ABSTRACT

A film forming apparatus forms a cured film by curing a curable composition placed on a substrate. The apparatus includes a substrate holding unit configured to hold the substrate, a heating unit configured to heat the curable composition placed on the substrate, an irradiation unit configured to irradiate the curable composition with curing light, a cooling unit configured to cool the substrate holding unit, and a lifting mechanism configured to move the substrate holding unit up and down so as to place the substrate holding unit at a first position where the heating unit heats the curable composition and the irradiation unit irradiates the curable composition with curing light and a second position where the substrate holding unit is placed on the cooling unit and is cooled by the cooling unit.

### BACKGROUND OF THE INVENTION

### Field of the Invention

The present invention relates to a film forming apparatus, a film forming method, and an article manufacturing method.

### Description of the Related Art

Japanese Patent Laid-Open No. 2020-61490 discloses a film forming apparatus that forms a film made of a cured material by bringing a curable composition placed on a substrate into contact with a flat surface, heating the curable composition to decrease its viscosity so as to conform the curable composition to the flat surface, and then curing the curable composition. This film forming apparatus includes a moving mechanism that moves a substrate in the horizontal direction between a first position where a substrate holding unit receives the substrate and a second position where a curing unit cures a curable composition.

The substrate holding unit holding a substrate can be heated at the time of heating a curable composition. When the substrate holding unit is heated, the substrate holding unit can deform, and the positioning accuracy of the substrate holding unit can deteriorate. This can decrease the reproducibility of the processing of forming a cured film on the substrate. In addition, the temperature of the substrate holding unit changes for each substrate when the substrate holding unit receives a substrate. This can change, for each substrate, the conditions under which a substrate is processed, thus decreasing the reproducibility of the processing of forming a cured film on a substrate.

### SUMMARY OF THE INVENTION

The present invention provides a technique advantageous in forming a cured film on a substrate with high reproducibility.

One of aspects of the present invention provides a film forming apparatus that forms a cured film by curing a curable composition placed on a substrate, the apparatus comprising: a substrate holding unit configured to hold the substrate; a heating unit configured to heat the curable composition placed on the substrate; an irradiation unit configured to irradiate the curable composition with curing light; a cooling unit configured to cool the substrate holding unit; and a lifting mechanism configured to move the substrate holding unit up and down so as to place the substrate holding unit at a first position where the heating unit heats the curable composition and the irradiation unit irradiates the curable composition with curing light and a second position where the substrate holding unit is placed on the cooling unit and is cooled by the cooling unit.

Further features of the present invention will become apparent from the following description of exemplary embodiments with reference to the attached drawings.

### BRIEF DESCRIPTION OF THE DRAWINGS

FIGS. 1A to 1E are sectional views schematically showing a film forming method according to an embodiment;

FIGS. 2A to 2E are sectional views schematically showing a film forming method according to another embodiment;

FIGS. 3A to 3D are views schematically showing a film forming apparatus and a film forming method according to the first embodiment;

FIGS. 4A to 4D are views schematically showing a film forming apparatus and a film forming method according to the second embodiment; and

FIGS. 5A to 5D are views showing a film forming apparatus and a film forming method according to the third embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

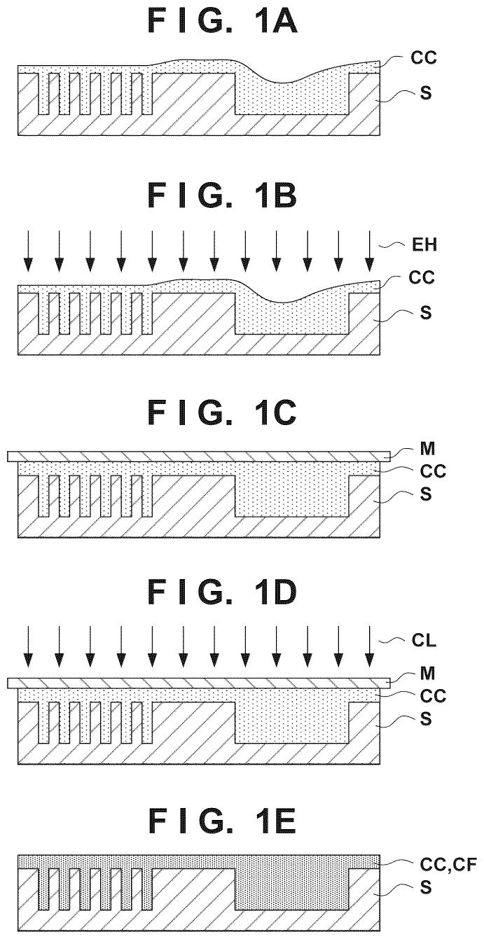

FIGS. 1A to 1E are sectional views schematically showing a film forming method according to an embodiment. The film forming method forms a cured film CF by curing a curable composition CC placed on a substrate S. In the step shown in FIG. 1A, the curable composition CC can be applied or placed on the substrate S. The substrate S can have a concave-convex pattern on the surface. The curable composition CC can be applied or placed on the surface of the substrate S by, for example, a spin coat method. The curable composition CC can have a viscosity suitable for the spin coat method at 25° C. (for example, 10⁻³ Pa·S to 10⁶ Pa·S).

In the step shown in FIG. 1B, energy EH for heating is supplied to the curable composition CC on the substrate S to heat the curable composition CC to a predetermined temperature. This decreases the viscosity of the curable composition CC. The predetermined temperature can fall within the range of, for example, 100° C. to 200° C.

In the step shown in FIG. 1C, a mold M having a flat surface can be placed on the heated curable composition CC on the substrate S so as to bring the flat surface into contact with the curable composition CC. The supply of the energy EH for heating to the curable composition CC may be stopped before the flat surface of the mold M is brought into contact with the curable composition CC or may be continued after the flat surface of the mold M is brought into contact with the curable composition CC. Alternatively, the supply of the energy EH for heating to the curable composition CC may be started after the flat surface of the mold M is brought into contact with the curable composition CC. The upper surface of the curable composition CC whose viscosity is reduced by heating can be planarized so as to conform to the flat surface of the mold M.

In the step shown in FIG. 1D, the curable composition CC on the substrate S is irradiated with curing light (for example, ultraviolet light) CL to cure the curable composition CC. This can form the cured film CF of the curable composition CC.

In the above example, the cured film CF having the planarized upper surface is formed by using the mold M having the flat surface. However, the cured film CF to which the pattern of the mold M is transferred may be formed by using the mold M having the pattern. The envelope surface of the upper surface of the cured film CF to which the pattern is transferred can have a flat surface.

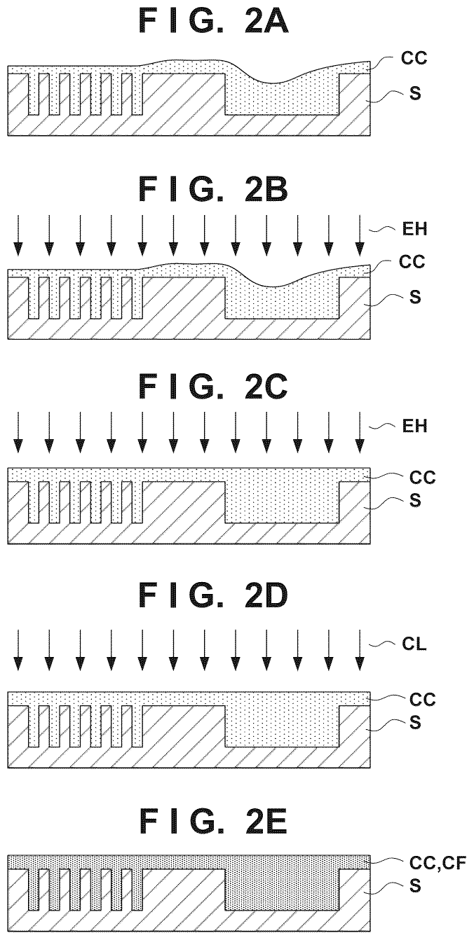

FIGS. 2A to 2E are sectional views schematically showing a film forming method according to another embodiment. The film forming method forms the cured film CF by curing the curable composition CC placed on the substrate S. In the step shown in FIG. 2A, the curable composition CC can be applied or placed on the substrate S. The substrate S can have a concave-convex pattern on its surface. The curable composition CC can be applied or placed on the surface of the substrate S by, for example, the spin coat method. The curable composition CC can have a viscosity suitable for the spin coat method at 25° C. (for example, 10⁻³ Pa·S to 10⁶ Pa·S).

In the step shown in FIGS. 2B and 2C, the energy EH for heating is supplied to the curable composition CC on the substrate S to heat the curable composition CC to a predetermined temperature. This decreases the viscosity of the curable composition CC. The predetermined temperature can be a temperature within the range of 100° C. to 200° C. The heated curable composition CC can form a flat or planarized upper surface by reflow.

In the step shown in FIG. 2D, the cured film CF of the curable composition CC can be formed by irradiating the curable composition CC on the substrate S with curing light (for example, ultraviolet light) CL to cure the curable composition CC.

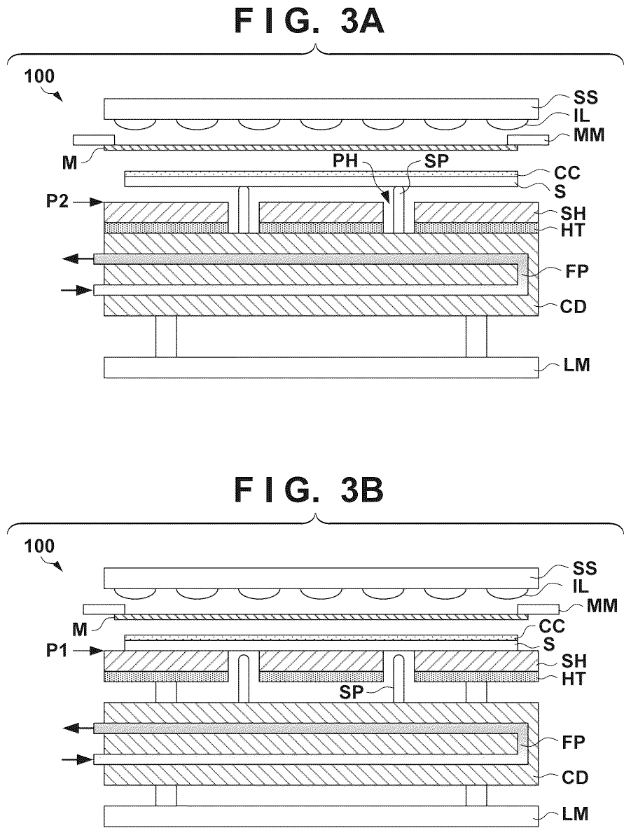

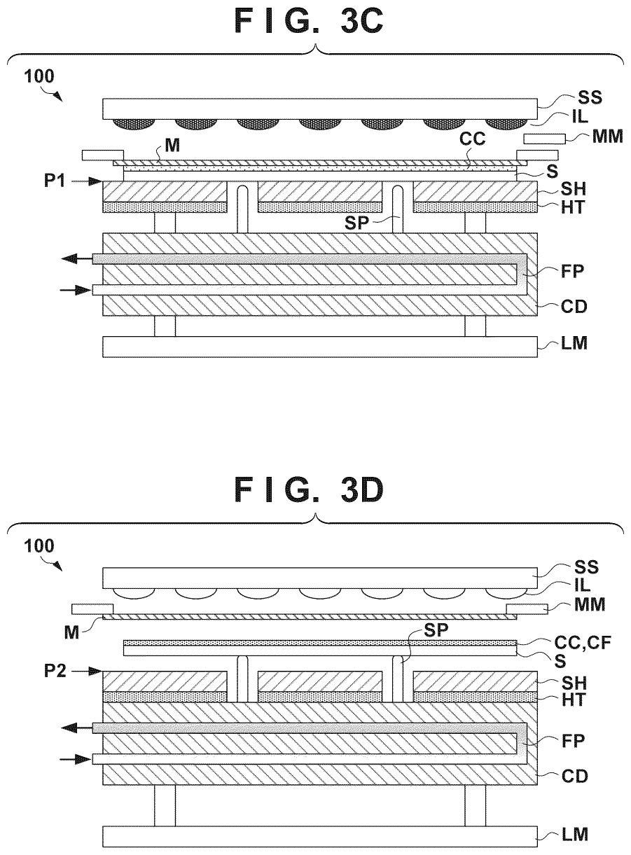

FIGS. 3A to 3D schematically show a film forming apparatus 100 and a film forming method according to the first embodiment. The film forming apparatus 100 is configured to form the cured film CF by curing the curable composition CC placed on the substrate S. The film forming apparatus 100 can be configured to form a planarized film as the cured film CF by using a mold having a flat surface as the mold M. Alternatively, the film forming apparatus 100 can be configured to form the cured film CF to which the pattern of the mold M is transferred by using a mold having a pattern as the mold M.

The film forming apparatus 100 can include a substrate holding unit SH that holds the substrate S, a heating unit HT that heats the curable composition CC placed on the substrate S, an irradiation unit IL that irradiates the curable composition CC with curing light, and a cooling unit CD that cools the substrate holding unit SH. The curable composition CC is a photo-curable composition that is cured by irradiation with curing light. The curable composition CC contains at least a polymerizable compound and a photopolymerization initiator and may further contain a non-polymerizable compound or a solvent. A non-polymerizable compound is at least one type of compound selected from the group consisting of a sensitizer, a hydrogen donor, an internal mold release agent, a surfactant, an antioxidant, a polymer component, and the like. The curable composition CC can be placed on the substrate S by a spin coater or a slit coater. The substrate S can include, for example, at least one patterned layer on a semiconductor substrate such as a silicon substrate or a compound semiconductor substrate.

The substrate holding unit SH can hold the substrate S with, for example, a suction force such as a vacuum suction force or an electrostatic suction force or by mechanical clamping. Alternatively, the substrate holding unit SH may hold the substrate S without exerting any suction force to the substrate S. The irradiation unit IL can be configured to irradiate the curable composition CC with curing light for curing the curable composition CC (for example, ultraviolet light). The irradiation unit IL can be configured to irradiate the curable composition CC with curing light through the mold M. Alternatively, the irradiation unit IL can be configured to irradiate the curable composition CC with curing light through a substrate. The film forming apparatus 100 can include a support mechanism SS that supports one or a plurality of irradiation units IL.

The heating unit HT can be configured to supply heat to the substrate S through thermal migration. The heating unit HT can include, for example, a resistive element that generates heat. The heating unit HT can provide heat to the substrate S through the substrate holding unit SH. The cooling unit CD can be configured to cool the substrate holding unit SH and the heating unit HT by dissipating heat from the substrate holding unit SH and the heating unit HT. The cooling unit CD can include, for example, a flow path FP forming part of a circulation system that circulates refrigerant. The circulation system can be provided with a cooling device that cools the refrigerant.

The film forming apparatus 100 can include a lifting mechanism LM that moves the substrate holding unit SH up and down. The lifting mechanism LM can move the substrate holding unit SH up and down so as to place the substrate holding unit SH at a first position P1 and a second position P2. The first position P1 is a position where the heating unit HT heats the curable composition CC and the irradiation unit IL irradiates a curable composition with curing light. The second position P2 is a position where the substrate holding unit SH is cooled by the cooling unit CD. At the second position P2, the substrate holding unit SH can be placed on the cooling unit CD.

The heating unit HT may be placed on the substrate holding unit SH and can be fixed to the lower surface of the substrate holding unit SH. The heating unit HT may be embedded in, for example, the substrate holding unit SH. The irradiation unit IL can be placed above the cooling unit CD. The first position P1 can be set above the second position P2. As shown in FIGS. 3A and 3D, when the substrate holding unit SH is at the second position P2, the substrate S is spaced apart from the substrate holding unit SH.

The substrate holding unit SH can have a plurality of through holes PH. The film forming apparatus 100 can have a plurality of support pins SP that are placed so as to respectively extend through the plurality of through holes PH. As shown in FIGS. 3B and 3C, when the substrate holding unit SH is placed at the first position P1, the substrate S can be held by the substrate holding unit SH. As shown in FIGS. 3A and 3D, when the substrate holding unit SH is placed at the second position P2, the substrate S is supported by the plurality of support pins SP. The plurality of support pins SP can be placed so as to protrude upward from the cooling unit CD.

As shown in FIG. 3A, while the substrate holding unit SH is placed at the second position P2, the substrate S coated with the curable composition CC can be placed on the plurality of support pins SP by a transfer mechanism (not shown). Note that the curable composition CC may be placed on the substrate S in the film forming apparatus 100 or may be placed on the substrate S by another apparatus. While the substrate S is supported by the plurality of support pins SP and the substrate holding unit SH is placed at the second position P2 as shown in FIG. 3A, the lifting mechanism LM can drive the substrate holding unit SH upward to the first position P1 by the lifting mechanism LM as shown in FIG. 3B. In the process in which the substrate holding unit SH moves from the second position P2 to the first position P1, the substrate S can be transferred from the plurality of support pins SP to the substrate holding unit SH. While the substrate S is supported by the substrate holding unit SH and the substrate holding unit SH is placed at the first position P1 as shown in FIG. 3C, the lifting mechanism LM can drive the substrate holding unit SH downward to the second position P2 as shown in FIG. 3D. In the process in which the substrate holding unit SH moves from the first position P1 to the second position P2, the substrate S can be transferred from the substrate holding unit SH to the plurality of support pins SP. The substrate S on which the cured film CF of the curable composition CC is formed can be removed from the plurality of support pins SP by the transfer mechanism (not shown).

The film forming apparatus 100 can include a driving mechanism MM that places the mold M on the curable composition CC on the substrate S. The driving mechanism MM can be configured to place the mold M on the curable composition CC before the irradiation unit IL irradiates the curable composition CC with curing light after the heating unit HT heats the curable composition CC. For example, the driving mechanism MM can be configured to place the mold M on the curable composition CC before the irradiation unit IL irradiates the curable composition CC with curing light after the heating unit HT heats the curable composition CC. Alternatively, the driving mechanism MM may be configured to place the mold M on the curable composition CC before the heating unit HT heats the curable composition CC. Alternatively, the film forming apparatus 100 may be provided with a structure having the mold M placed on the curable composition CC on the substrate S.

The film forming apparatus 100 can include a control unit (not shown) that controls at least some or all of the irradiation unit IL, the heating unit HT, the lifting mechanism LM, the cooling unit CD, and the driving mechanism MM. The control unit can be formed of a programmable logic device (PLD) such as a field programmable gate array (FPGA) or an application specific integrated circuit (ASIC), a general-purpose or dedicated computer incorporating programs, or a combination of all or some of them.

The operation of the film forming apparatus 100 according to the first embodiment exemplarily shown in FIGS. 3A to 3D will be exemplarily described. First of all, as shown in FIG. 3A, while the substrate holding unit SH is placed at the second position P2, the substrate S coated with the curable composition CC is transferred onto the plurality of support pins SP by a transfer mechanism (not shown) and can be supported by the plurality of support pins SP. Subsequently, as shown in FIG. 3B, the lifting mechanism LM drives the substrate holding unit SH to the first position P1. In this process, the substrate S can be transferred from the plurality of support pins SP to the substrate holding unit SH. After the substrate holding unit SH starts to move from the second position P2 to the first position P1, that is, after the substrate holding unit SH or the heating unit HT moves away from the cooling unit CD, the heating unit HT can start heating. Making the substrate holding unit SH hold the substrate S will cause the heating unit HT to start heating the curable composition CC on the substrate S. Heating the curable composition CC will decrease the viscosity of the curable composition CC and can start the reflow of the curable composition CC.

As shown in FIG. 3C, the driving mechanism MM can place the mold M on the curable composition CC. The driving mechanism MM may start to bring the mold M into contact with the curable composition CC while the mold M is deformed to become convex downward. The space between the substrate S and the mold M can be filled with the curable composition CC so as to discharge the gas in the space. Heating the curable composition CC with the heating unit HT can promote filling the space between the substrate S and the mold M with the curable composition CC. Upon completion of such filling, the irradiation unit IL irradiates the curable composition CC with curing light. This can cure the curable composition CC. The irradiation unit IL can irradiate the curable composition CC with curing light through the mold M. Note that a mode that does not use the mold M does not require the driving mechanism MM.

As shown in FIG. 3D, the lifting mechanism LM drives the substrate holding unit SH downward from the first position P1 to the second position P2. In this process, the substrate S is transferred from the substrate holding unit SH to the plurality of support pins SP. The transfer mechanism (not shown) can remove the substrate S, on which the cured film CF of the curable composition CC is formed, from on the plurality of support pins SP. While the substrate holding unit SH is placed at the second position P2, the cooling unit CD can cool the substrate holding unit SH and the heating unit HT to a target temperature. According to the first embodiment, therefore, since the substrate holding unit SH is cooled every time the processing of the substrate S is completed, the plurality of substrates S can be processed under the same conditions. For example, it is possible to uniform the temperature of the substrate holding unit SH when the substrate S comes into contact with the substrate holding unit SH and the time required for filling through out the plurality of substrates S. This makes it possible to improve the reproducibility of the processing of forming cured films on the plurality of substrates S.

The film forming method executed by the film forming apparatus 100 forms the cured film CF by curing the curable composition CC placed on the substrate S. The film forming method can include a step of holding the substrate S with the substrate holding unit SH and moving the substrate holding unit SH to the first position P1 and a step of heating the curable composition CC while the substrate holding unit SH is placed at the first position P1. In addition, the film forming method can include a step of curing the curable composition CC by irradiating the curable composition CC with curing light while the substrate holding unit SH is placed at the first position P1. The film forming method can also include a step of moving the substrate holding unit SH from the first position P1 to the second position P2 after the curable composition CC is cured and a step of cooling the substrate holding unit SH while the substrate holding unit SH is placed at the second position P2. The film forming method can also include a step of placing the mold M on the curable composition CC before the start of a step of irradiating the curable composition CC with curing light after the start of a step of heating the curable composition CC.

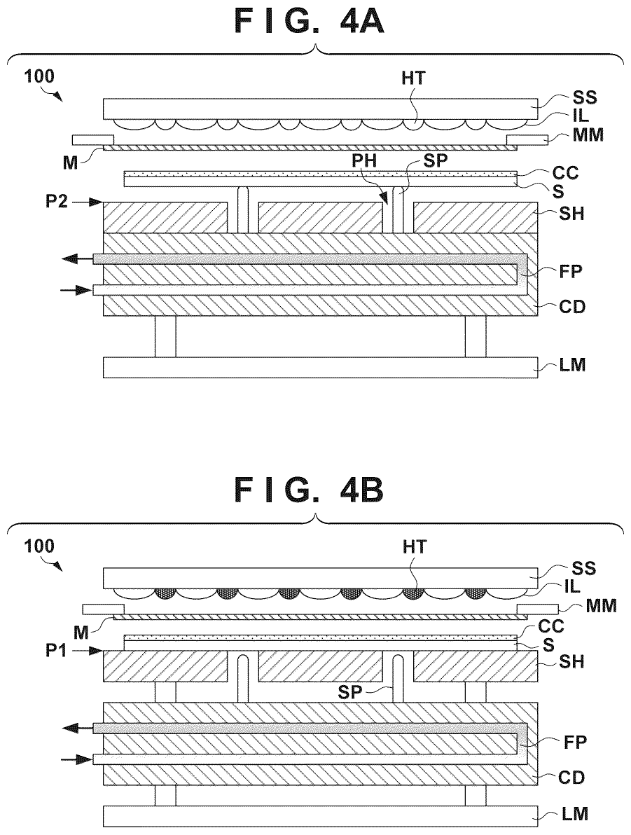

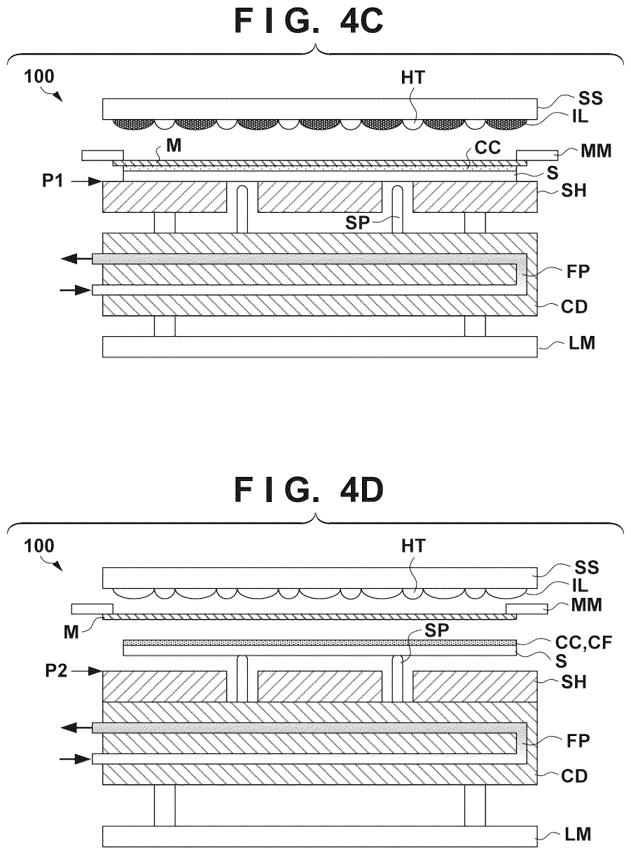

FIGS. 4A to 4D schematically show a film forming apparatus 100 and a film forming method according to the second embodiment. Matters that are not mentioned below concerning the film forming apparatus 100 and the film forming method according to the second embodiment can comply with the first embodiment unless any contradiction occurs. The second embodiment can differ from the first embodiment in the arrangement and placement of a heating unit HT.

In the second embodiment, the heating unit HT can be configured to heat a curable composition CC by irradiating the curable composition CC with heat rays (infrared rays). The heating unit HT can be configured to irradiate the curable composition CC with heat rays through a mold M. Alternatively, the heating unit HT may be configured to irradiate the curable composition CC with heat rays through a substrate S. In the second embodiment, one or a plurality of heating units HT can be supported by a support mechanism SS together with one or a plurality of irradiation units IL.

The operation of the film forming apparatus 100 according to the second embodiment exemplarily shown in FIGS. 4A to 4D will be described below. First of all, as shown in FIG. 4A, while a substrate holding unit SH is placed at a second position P2, the substrate S coated with the curable composition CC can be transferred onto a plurality of support pins SP by a transfer mechanism (not shown) and supported by the plurality of support pins SP. Subsequently, as shown in FIG. 4B, a lifting mechanism LM drives the substrate holding unit SH upward up to a first position P1. In this process, the substrate S is transferred from the plurality of support pins SP to the substrate holding unit SH. The heating unit HT then irradiates the curable composition CC with heat rays to heat the curable composition CC. Heating the curable composition CC can decrease the viscosity of the curable composition CC and start the reflow of the curable composition CC.

Subsequently, as shown in FIG. 4C, a driving mechanism MM can place the mold M on the curable composition CC. The driving mechanism MM may start to bring the mold M into contact with the curable composition CC while the mold M is deformed so as to become convex downward. The space between the substrate S and the mold M can be filled with the curable composition CC so as to discharge the gas from the space. Heating the curable composition CC with the heating unit HT can promote filling the space between the substrate S and the mold M with the curable composition CC. Upon completion of such filling, the irradiation unit IL irradiates the curable composition CC with curing light. This can cure the curable composition CC. The irradiation unit IL can irradiate the curable composition CC with curing light through the mold M. Note that a mode that does not use the mold M does not require the driving mechanism MM.

Subsequently, as shown in FIG. 4D, the lifting mechanism LM drives the substrate holding unit SH downward from the first position P1 to the second position P2. In this process, the substrate S can be transferred from the substrate holding unit SH to the plurality of support pins SP. The transfer mechanism (not shown) can remove the cured film CF of the curable composition CC from on the plurality of support pins SP. While the substrate holding unit SH is placed at the second position P2, the cooling unit CD can come into contact with the substrate holding unit SH and cool the substrate holding unit SH to a target temperature. According to the second embodiment, since the substrate holding unit SH is cooled every time the processing of one substrate is completed, the plurality of substrates S can be processed under the same conditions. For example, it is possible to uniform the temperature of the substrate holding unit SH when the substrate S comes into contact with the substrate holding unit SH and the time required for filling through out the plurality of substrates S. This makes it possible to improve the reproducibility of the processing of forming cured films on the plurality of substrates S.

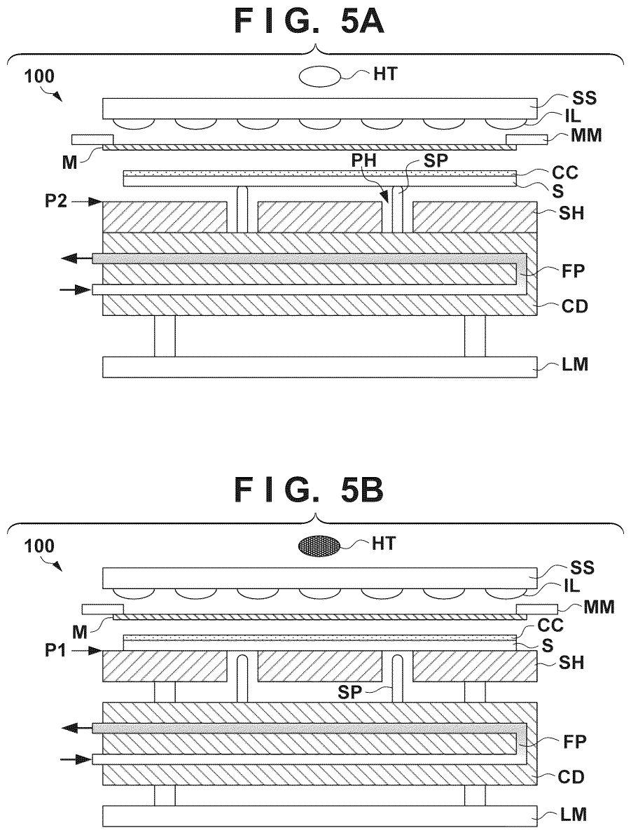

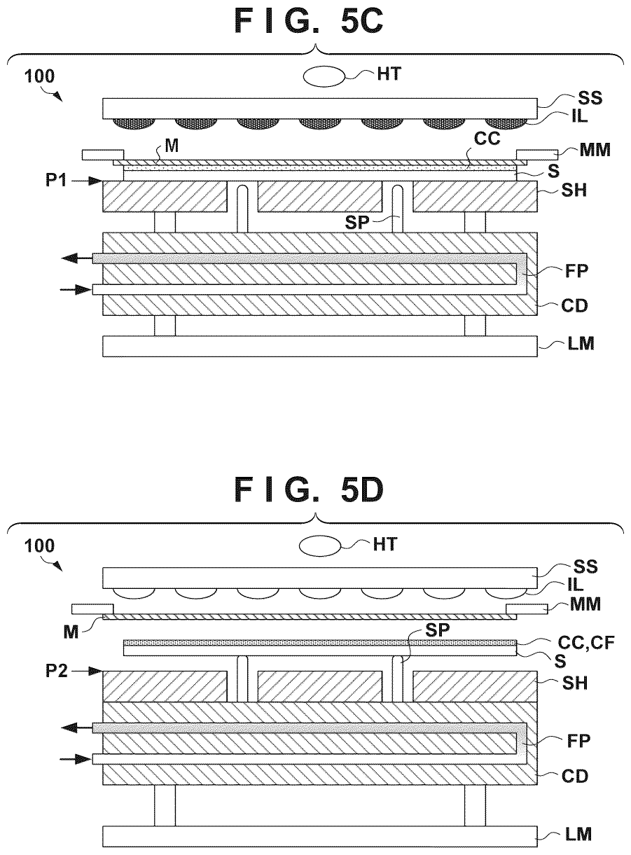

FIGS. 5A to 5D schematically show a film forming apparatus 100 and a film forming method according to the third embodiment. Matters that are not mentioned below concerning the film forming apparatus 100 and the film forming method according to the third embodiment can comply with the first embodiment unless any contradiction occurs. The third embodiment can differ from the first embodiment in the arrangement and placement of a heating unit HT.

In the third embodiment, the heating unit HT can be configured to heat a curable composition CC by irradiating the curable composition CC with electromagnetic waves. The heating unit HT can be configured to irradiate the curable composition CC with electromagnetic waves through a mold M. Alternatively, the heating unit HT may be configured to irradiate the curable composition CC with electromagnetic waves through a substrate S.

The operation of the film forming apparatus 100 according to the third embodiment exemplarily shown in FIGS. 5A to 5D will be described below. First of all, as shown in FIG. 5A, while a substrate holding unit SH is placed at a second position P2, the substrate S coated with the curable composition CC can be transferred onto a plurality of support pins SP by a transfer mechanism (not shown) and supported by the plurality of support pins SP. Subsequently, as shown in FIG. 5B, a lifting mechanism LM drives the substrate holding unit SH upward to a first position P1. In this process, the substrate S is transferred from the plurality of support pins SP to the substrate holding unit SH. The heating unit HT then irradiates the curable composition CC with electromagnetic waves to heat the curable composition CC. Heating the curable composition CC can decrease the viscosity of the curable composition CC and start the reflow of the curable composition CC.

Subsequently, as shown in FIG. 5C, a driving mechanism MM can place the mold M on the curable composition CC. The driving mechanism MM may start to bring the mold M into contact with the curable composition CC while the mold M is deformed so as to become convex downward. The space between the substrate S and the mold M can be filled with the curable composition CC so as to discharge the gas from the space. Heating the curable composition CC with the heating unit HT can promote filling the space between the substrate S and the mold M with the curable composition CC. Upon completion of such filling, an irradiation unit IL irradiates the curable composition CC with curing light. This can cure the curable composition CC. The irradiation unit IL can irradiate the curable composition CC with curing light through the mold M. Note that a mode that does not use the mold M does not require the driving mechanism MM.

Subsequently, as shown in FIG. 5D, the lifting mechanism LM drives the substrate holding unit SH downward from the first position PI to the second position P2. In this process, the substrate S can be transferred from the substrate holding unit SH to the plurality of support pins SP. The transfer mechanism (not shown) can remove the cured film CF of the curable composition CC from on the plurality of support pins SP. While the substrate holding unit SH is placed at the second position P2, the cooling unit CD can come into contact with the substrate holding unit SH and cool the substrate holding unit SH to a target temperature. According to the second embodiment, since the substrate holding unit SH is cooled every time the processing of one substrate is completed, the plurality of substrates S can be processed under the same conditions. For example, it is possible to uniform the temperature of the substrate holding unit SH when the substrate S comes into contact with the substrate holding unit SH and the time required for filling through out the plurality of substrates S. This makes it possible to improve the reproducibility of the processing of forming cured films on the plurality of substrates S.

An article manufacturing method of manufacturing an article such as semiconductor device, a display device, or a micro electro mechanical systems (MEMS) will be described below. The article manufacturing method can include a film forming step of forming the cured film CF of the curable composition CC on the substrate S by a film forming method represented by the plurality of embodiments described above and a processing step of obtaining an article by processing the substrate S having undergone the film forming step. The processing step can include, for example, a step of forming a film such as a conductive film or an insulating film on the cured film CF, a step of forming a resist pattern on the film by a photolithography process and a step of etching the film through an opening portion of the resist pattern.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-002789, filed Jan. 11, 2024, which is hereby incorporated by reference herein in its entirety.

What is claimed is:

1. A film forming apparatus that forms a cured film by curing a curable composition placed on a substrate, the apparatus comprising:
a substrate holding unit configured to hold the substrate;
a heating unit configured to heat the curable composition placed on the substrate;
an irradiation unit configured to irradiate the curable composition with curing light;
a cooling unit configured to cool the substrate holding unit; and
a lifting mechanism configured to move the substrate holding unit up and down so as to place the substrate holding unit at a first position where the heating unit heats the curable composition and the irradiation unit irradiates the curable composition with curing light and a second position where the substrate holding unit is placed on the cooling unit and is cooled by the cooling unit.

2. The apparatus according to claim 1, wherein the irradiation unit is placed above the cooling unit, and
the first position is positioned above the second position.

3. The apparatus according to claim 2, wherein in a case where the substrate holding unit is placed at the second position, the substrate is spaced apart from the substrate holding unit.

4. The apparatus according to claim 3, wherein the substrate holding unit includes a plurality of through holes,
the film forming apparatus includes a plurality of support pins that are placed so as to respectively extend through the plurality of through holes, and
the substrate is held by the substrate holding unit in a case where the substrate holding unit is placed at the first position, and the substrate is supported by the plurality of support pins in a case where the substrate holding unit is placed at the second position.

5. The apparatus according to claim 4, wherein the plurality of support pins are placed so as to protrude upward from the cooling unit.

6. The apparatus according to claim 1, wherein the heating unit is placed on the substrate holding unit.

7. The apparatus according to claim 6, wherein the heating unit is fixed to a lower surface of the substrate holding unit.

8. The apparatus according to claim 1, wherein the heating unit irradiates the curable composition with heat rays.

9. The apparatus according to claim 1, wherein the heating unit irradiates the curable composition with electromagnetic waves.

10. The apparatus according to claim 1, further comprising a driving mechanism configured to place a mold on the curable composition on the substrate.

11. The apparatus according to claim 10, wherein the heating unit irradiates the curable composition with heat rays through the mold.

12. The apparatus according to claim 10, wherein the heating unit irradiates the curable composition with electromagnetic waves through the mold.

13. The apparatus according to claim 10, wherein the driving mechanism places a mold on the curable composition before the irradiation unit irradiates the curable composition with the curing light after the heating unit starts to heat the curable composition.

14. The apparatus according to claim 10, wherein a planarized film is formed as the cured film by using a mold having a flat surface as the mold.

15. The apparatus according to claim 10, wherein a mold having a pattern is used as the mold to form the cured film to which the pattern is transferred.

16. A film forming method of forming a cured film by curing a curable composition placed on a substrate, the method comprising:
holding a substrate with a substrate holding unit and moving the substrate holding unit to a first position;
heating the curable composition while the substrate holding unit is placed at the first position;
curing the curable composition by irradiating the curable composition with curing light while the substrate holding unit is placed at the first position;
moving the substrate holding unit from the first position to a second position after the curable composition is cured; and
cooling the substrate holding unit while the substrate holding unit is placed at the second position.

17. The method according to claim 16, wherein the first position is positioned above the second position.

18. The method according to claim 16, further comprising placing a mold on the curable composition before the curable composition is irradiated with the curing light after the curable composition is heated.

19. The method according to claim 16, wherein in a process of moving the substrate holding unit from the first position to the second position, the substrate is transferred from the substrate holding unit to a plurality of support pins.

20. An article manufacturing method comprising:
forming a cured film of a curable composition on a substrate; and
obtaining an article by processing the substrate having undergone the forming the cured film,
wherein the forming the cured film comprising:
holding, by a substrate holding unit, the substrate on which the curable composition is placed, and moving the substrate holding unit to a first position;
heating the curable composition on the substrate while the substrate holding unit is placed at the first position;
curing the curable composition by irradiating the curable composition with curing light while the substrate holding unit is placed at the first position;
moving the substrate holding unit from the first position to a second position after the curable composition is cured; and
cooling the substrate holding unit while the substrate holding unit is placed at the second position.
